(19) United States
(12) Patent Application Publication
(10) Pub. No.: US 2013/0120415 A1
(43) Pub. Date: May 16, 2013

(54) COMBINED RESONATORS AND PASSIVE CIRCUIT COMPONENTS ON A SHARED SUBSTRATE

(71) Applicants: Chengjie Zuo, Santee, CA (US); Chi Shun Lo, San Diego, CA (US); Sanghoon Joo, Sunnyvale, CA (US); Changhan Yun, San Diego, CA (US); Jonghae Kim, San Diego, CA (US)

(72) Inventors: Chengjie Zuo, Santee, CA (US); Chi Shun Lo, San Diego, CA (US); Sanghoon Joo, Sunnyvale, CA (US); Changhan Yun, San Diego, CA (US); Jonghae Kim, San Diego, CA (US)

(73) Assignee: QUALCOMM MEMS TECHNOLOGIES, INC., San Diego, CA (US)

(21) Appl. No.: 13/295,967

(22) Filed: Nov. 14, 2011

(51) Int. Cl. G06F 13/14; H01L 41/02; H01L 41/22; B05D 5/12; H03H 9/54

(52) U.S. Cl. 345/520; 310/348; 427/100; 427/79; 333/187

(57) ABSTRACT

This disclosure provides implementations of electromechanical systems combined resonator and passive circuit component structures, devices, apparatus, systems, and related processes. In one aspect, the device includes a piezoelectric resonator structure formed over an insulating substrate. A portion of the piezoelectric resonator structure is spaced apart from the substrate by a first gap. A passive circuit component structure such as an inductor or a capacitor is formed over the insulating substrate. A portion of the passive circuit component structure is spaced apart from the substrate by a second gap. The first gap and the second gap are defined by removal of a sacrificial (SAC) layer.

### TECHNICAL FIELD

This disclosure relates generally to resonators and more specifically to electromechanical systems piezoelectric resonators and other passive circuit components.

### DESCRIPTION OF THE RELATED TECHNOLOGY

Electromechanical systems (EMS) include devices having electrical and mechanical elements, transducers such as actuators and sensors, optical components (including mirrors), and electronics. Electromechanical systems can be manufactured at a variety of scales including, but not limited to, microscales and nanoscales. For example, microelectromechanical systems (MEMS) devices can include structures having sizes ranging from about one micron to hundreds of microns or more. Nanoelectromechanical systems (NEMS) devices can include structures having sizes smaller than one micron including, for example, sizes smaller than several hundred nanometers. Electromechanical elements may be created using deposition, etching, lithography, and/or other micromachining processes that etch away parts of substrates and/or deposited material layers, or that add layers to form electrical, mechanical, and electromechanical devices.

One type of EMS device is called an interferometric modulator (IMOD). As used herein, the term interferometric modulator or interferometric light modulator refers to a device that selectively absorbs and/or reflects light using the principles of optical interference. In some implementations, an IMOD may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the IMOD. IMOD devices have a wide range of applications, and are anticipated to be used in improving existing products and creating new products, especially those with display capabilities.

Various electronic circuit components can be implemented at the EMS level.

### SUMMARY

The structures, devices, apparatus, systems, and processes of the disclosure each have several innovative aspects, no single one of which is solely responsible for the desirable attributes disclosed herein.

Disclosed are implementations of combined electromechanical systems resonator and passive circuit component structures, devices, apparatus, systems, and related fabrication processes.

One innovative aspect of the subject matter described in this disclosure can be implemented in a process for forming a combined resonator and passive circuit component device. The process includes: forming a sacrificial (SAC) layer over an insulating substrate having a resonator region and a passive component region, the SAC layer including a resonator portion situated in the resonator region and a passive portion situated in the passive component region; forming a first conductive layer over the SAC layer, the first conductive layer including a resonator portion situated in the resonator region; forming a piezoelectric layer over the first conductive layer, the piezoelectric layer including a resonator portion situated in the resonator region and a passive portion situated in the passive component region; forming a second conductive layer over the piezoelectric layer, the second conductive layer including a resonator portion situated in the resonator region and a passive portion situated in the passive component region; and removing the SAC layer to define a first gap and a second gap. The resonator portions of the layers define a piezoelectric resonator structure at least partially overlaying the first gap. The passive portions of the layers defining a passive circuit component structure such as an inductor or a capacitor at least partially overlaying the second gap. In some implementations, the first conductive layer further includes a passive portion situated in the passive component region.

In some implementations, the process further includes forming one or more interconnect layers over the passive portion of the second conductive layer. The one or more interconnect layers can include one or more first conductive contacts coupled to the passive component structure. The one or more interconnect layers can further include one or more second conductive contacts coupled to the piezoelectric resonator structure.

Another innovative aspect of the subject matter described in this disclosure can be implemented in a process for forming a combined resonator and passive circuit component device. The process includes: forming a sacrificial (SAC) layer over a substrate having a resonator region, a first passive component region, a second passive component region, and a third passive component region, the SAC layer including a resonator portion situated in the resonator region and a passive portion situated in the first passive component region; forming a first conductive layer over the SAC layer, the first conductive layer including a resonator portion situated in the resonator region, a first passive portion situated in the first passive component region, a second passive portion situated in the second passive component region, and a third passive portion situated in the third passive component region; forming a piezoelectric layer over the first conductive layer, the piezoelectric layer including a resonator portion situated in the resonator region, a first passive portion situated in the first passive component region, a second passive portion situated in the second passive component region, and a third passive portion situated in the third passive component region; forming a first via in the first passive component region of the piezoelectric layer and a second via in the second passive component region of piezoelectric layer; forming a second conductive layer over the piezoelectric layer, the second conductive layer including a resonator portion situated in the resonator region, a first passive portion situated in the first via of the first passive component region and coupled to the first passive portion of the first conductive layer, a second passive portion situated in the second via of the second passive component region and coupled to the second passive portion of the first conductive layer, and a third passive portion situated in the third passive component region; forming a third conductive layer over the second conductive layer, the third conductive layer including a first passive portion situated in the first passive component region and coupled to the first passive portion of the second conductive layer, and a second passive portion situated in the second passive component region and coupled to the second passive portion of the second conductive layer; and removing the SAC layer to define a first gap and a second gap. The resonator portions of the layers define a piezoelectric resonator structure at least partially overlaying the first gap. The first passive portions of the layers define a first passive circuit component structure at least partially overlaying the second gap. The second passive portions of the layers define a second passive circuit component structure, and the third passive portions of the layers defining a third passive circuit component structure.

In some implementations, the first passive portion of the third conductive layer has a spiral shape. In some implementations, the first passive circuit component structure is an inductor, the second passive circuit component structure is a resistor, and the third passive circuit component structure is a capacitor.

Another innovative aspect of the subject matter described in this disclosure can be implemented in a combined resonator and passive circuit component device. The device includes a piezoelectric resonator structure formed over an insulating substrate. A portion of the piezoelectric resonator structure is spaced apart from the substrate by a first gap. A passive circuit component structure is formed over the insulating substrate. A portion of the passive circuit component structure is spaced apart from the substrate by a second gap. The first gap and the second gap are defined by removal of a sacrificial (SAC) layer.

In some implementations the piezoelectric resonator structure and the passive circuit component structure include a shared piezoelectric layer. In some implementations, the piezoelectric resonator structure and the passive circuit component structure include one or more shared conductive layers. In some implementations, the piezoelectric resonator structure and the passive circuit component structure include a shared interconnect layer.

Another innovative aspect of the subject matter described in this disclosure can be implemented in apparatus including piezoelectric resonator means for resonating in response to a first input signal. The piezoelectric resonator means is formed over an insulating substrate, and a portion of the piezoelectric resonator means is spaced apart from the substrate by a first gap. The apparatus also includes passive circuit component means for providing an electrical characteristic in response to a second input signal. The passive circuit component means is formed over the insulating substrate, and a portion of the passive circuit component means is spaced apart from the substrate by a second gap. The first gap and the second gap are defined by removal of a sacrificial (SAC) layer.

Details of one or more implementations of the subject matter described in this specification are set forth in the accompanying drawings and the description below. Although the examples provided in this disclosure are primarily described in terms of electromechanical systems (EMS) and microelectromechanical systems (MEMS)-based displays, the concepts provided herein may apply to other types of displays, such as liquid crystal displays, organic light-emitting diode (“OLED”) displays and field emission displays. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of a perspective view of a contour mode resonator (CMR) device.

FIG. 2A shows an example of a top view of a contour mode resonator (CMR) device.

FIG. 2B shows an example of a bottom view of the CMR device of FIG. 2A.

FIG. 2C shows an example of a top view of a CMR device.

FIG. 2D shows an example of a bottom view of the CMR device of FIG. 2C.

FIG. 3 shows an example of a perspective cross-sectional view of a CMR device.

FIG. 4 shows an example of a top view of a resonator device.

FIG. 5 shows an example of a perspective cross-sectional view of a resonator structure.

FIG. 6 shows an example of a flow diagram illustrating a process for forming a combined resonator and passive circuit component device.

FIGS. 7A-7E show examples of cross-sectional schematic illustrations of stages of combined resonator and passive circuit component device fabrication in accordance with a process, for instance, as represented in FIG. 6.

FIG. 8 shows an example of a flow diagram illustrating a process for forming a combined resonator and passive circuit component device.

FIGS. 9A-9F show examples of cross-sectional schematic illustrations of stages of combined resonator and passive circuit component device fabrication in accordance with a process, for instance, as represented in FIG. 8.

FIG. 10 shows an example of a flow diagram illustrating a process for forming a combined resonator and passive circuit component device.

FIGS. 11A-11F show examples of cross-sectional schematic illustrations of stages of combined resonator and passive circuit component device fabrication in accordance with a process, for instance, as represented in FIG. 10.

FIG. 12 shows an example of a top-down view of a combined resonator and passive circuit component device, for instance, as represented in FIG. 11F.

FIG. 13A shows an example of an isometric view depicting two adjacent pixels in a series of pixels of an interferometric modulator (IMOD) display device.

FIG. 13B shows an example of a system block diagram illustrating an electronic device incorporating an IMOD display.

FIGS. 14A and 14B show examples of system block diagrams illustrating a display device that includes a plurality of IMODs.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways.

The disclosed implementations include examples of structures and configurations of electromechanical systems resonator devices, such as contour mode resonators (CMR). Related apparatus, systems, and fabrication processes and techniques are also disclosed. CMRs are referred to as “contour mode” because of their substantially lateral and in-plane mode of vibration, as described in greater detail below. In the case of piezoelectric resonators, electrodes are generally disposed in contact with or in proximity to a piezoelectric material. For instance, the electrodes can be located on the same surface or on opposite surfaces of a layer of the piezoelectric material. An electric field applied between electrodes is transduced into a mechanical strain in the piezoelectric material. For instance, a time-varying electrical signal can be provided to an input electrode of the CMR and transduced to a corresponding time-varying mechanical motion. A portion of this mechanical energy can be transferred back to electrical energy at the input electrode or at a separate output electrode. The frequency of the input electrical signal that produces the greatest substantial amplification of the mechanical displacement in the piezoelectric material is generally referred to as a resonant frequency of the CMR.

In one or more implementations of the disclosed CMRs, the resonator structure is suspended in a cavity of a supporting structure and generally includes two conductive electrode layers, with a layer of piezoelectric material sandwiched between the two electrode layers. The resonator structure can be suspended in the cavity by specially designed tethers coupling the resonator structure to the supporting structure, as further explained below. These tethers are often fabricated in the layer stack of the resonator structure itself. The resonator structure can be acoustically isolated from the surrounding structural support and other apparatus by virtue of the cavity.

Some implementations described herein are based on a contour mode resonator configuration. In such implementations, the resonant frequency of a CMR can be substantially controlled by engineering the lateral dimensions of the piezoelectric material and electrodes. One benefit of such a construction is that multi-frequency RF filters, clock oscillators, transducers or other devices, each including one or more CMRs depending on the desired implementation, can be fabricated on the same substrate. For example, this may be advantageous in terms of cost and size by enabling compact, multi-band filter solutions for RF front-end applications on a single chip. In some examples, by co-fabricating multiple CMRs with different finger widths, as described in greater detail below, multiple frequencies can be addressed on the same die. In some examples, arrays of CMRs with different frequencies spanning a range from MHz to GHz can be fabricated on the same substrate.

With the disclosed CMRs, direct frequency synthesis for spread spectrum communication systems may be enabled by multi-frequency narrowband filter banks including high quality (Q) resonators, without the need for phase locked loops. The disclosed CMR implementations can provide for piezoelectric transduction with low motional resistance while maintaining high Q factors and appropriate reactance values that facilitate their interface with contemporary circuitry. Some examples of the disclosed laterally vibrating resonator structures provide the advantages of compact size, e.g., on the order of 100 um (micrometers) in length and/or width, low power consumption, and compatibility with high-yield mass-producible components.

Some of the disclosed processes and apparatus generally relate to the formation of a combined resonator and passive circuit component device. As described in greater detail below, a piezoelectric laterally vibrating resonator structure and one or more passive circuit component structures such as inductors, capacitors, and/or resistors can be formed on the same shared insulating substrate such as a glass substrate. In a simultaneous fabrication process for forming the respective structures, one or more processing steps can be shared, and one or more layers can be shared by both the resonator structure and the passive circuit component structures. For instance, a portion of a piezoelectric layer formed of a material such as aluminum nitride (AlN) can be sandwiched between conductive layers to define the vibrating resonator structure. A portion of the same piezoelectric layer also can define an element of one or more of the passive circuit component structures, such as a dielectric layer sandwiched between conductive plates of a capacitor, and/or a dielectric layer separating terminals of a spiral-shaped inductor. One or more of the conductive layers of the respective structures also can be shared, as described in greater detail below. Also, a single interconnect metal layer, or two or more adjacent contacting interconnect layers, can be deposited to provide conductive contacts with the structures.

In fabricating a combined resonator and passive circuit component device, portions of a shared sacrificial (SAC) layer formed of a material such as amorphous silicon (a-Si) or molybdenum (Mo) can be deposited on a substrate beneath elements of the resonator structure and the passive component structure(s). When the SAC layer is released, for instance, by exposing the device to a xenon difluoride (XeF₂) gas, gaps can be created such that the piezoelectric vibrating resonator structure is spaced apart from the substrate, as is the passive circuit component structure. Such gaps can minimize signal loss and provide a higher Q factor for the combined resonator and passive component device.

Particular implementations of the subject matter described in this disclosure can be implemented to realize one or more of the following potential advantages. The formation of resonators and passive circuit components using the disclosed MEMS fabrication techniques can reduce chip real estate occupied by such structures and components, since the various structures can be fabricated on the same substrate. Also, reductions in parasitic inductance, parasitic capacitance, and parasitic resistance of respective passive components can be achieved, thus improving signal throughput. For instance, by fabricating an inductor and a resonator on the same substrate/chip, as opposed to fabricating the same components on separate chips and connecting them on a printed circuit board (PCB), the parasitic inductance of the PCB can be essentially removed as a factor in circuit design. Such can be desirable in circuit applications having specifications for minimal inductances, e.g., on the order of nanohenries. In general, when one or more resonators and one or more passive components are fabricated on a shared substrate and in close proximity to each other, using some of the techniques disclosed herein, parasitic inductance, capacitance, and/or resistance can be virtually eliminated. Some implementations of the subject matter described in this disclosure can reduce steps of a fabrication process, as well as a packaging process, particularly since the disclosed components can be co-fabricated using shared steps and implemented as a one-chip solution. Lower fabrication costs are often a resulting benefit, as are lower packaging costs, both of which are often significant parts of the overall product cost.

The disclosed resonator and passive component structures can be fabricated on the same low-cost, high-performance, large-area insulating substrate, which, in some implementations, forms at least a portion of the supporting structure described herein. In some implementations, the insulating substrate on which the disclosed structures are formed can be made of display grade glass (alkaline earth boro-aluminosilicate) or soda lime glass. Other suitable insulating materials of which the insulating substrate can be made include silicate glasses, such as alkaline earth aluminosilicate, borosilicate, modified borosilicate, and others. Also, ceramic materials such as aluminum oxide (AlOx), yttrium oxide (Y₂O₃), boron nitride (BN), silicon carbide (SiC), aluminum nitride (AlNx), and gallium nitride (GaNx) can be used as the insulating substrate material. In some other implementations, the insulating substrate is formed of high-resistivity silicon. In some implementations, silicon On Insulator (SOI) substrates, gallium arsenide (GaAs) substrates, indium phosphide (InP) substrates, and plastic (polyethylene naphthalate or polyethylene terephthalate) substrates, e.g., associated with flexible electronics, also can be used. The substrate can be in conventional Integrated Circuit (IC) wafer form, e.g., 4-inch, 6-inch, 8-inch, 12-inch, or in large-area panel form. For example, flat panel display substrates with dimensions such as 370 mm×470 mm, 920 mm×730 mm, and 2850 mm×3050 mm, can be used.

In some implementations, the disclosed resonator structures are fabricated by depositing a SAC layer on the substrate; forming a lower electrode layer on the SAC layer; depositing a piezoelectric layer on the lower electrode layer; forming an upper electrode layer on the piezoelectric layer; and removing at least part of the SAC layer to define a cavity. The resulting resonator cavity separates at least a portion of the lower electrode layer from the substrate and provides openings along the sides of the resonator structure, as illustrated in the accompanying figures, to allow the resonator to vibrate and move in one or more directions with substantial elastic isolation from the remaining substrate. In some other implementations, a portion of the substrate itself serves as a SAC material. In these implementations, designated regions of the insulating substrate below the resonator structure can be removed, for example, by etching to define the cavity.

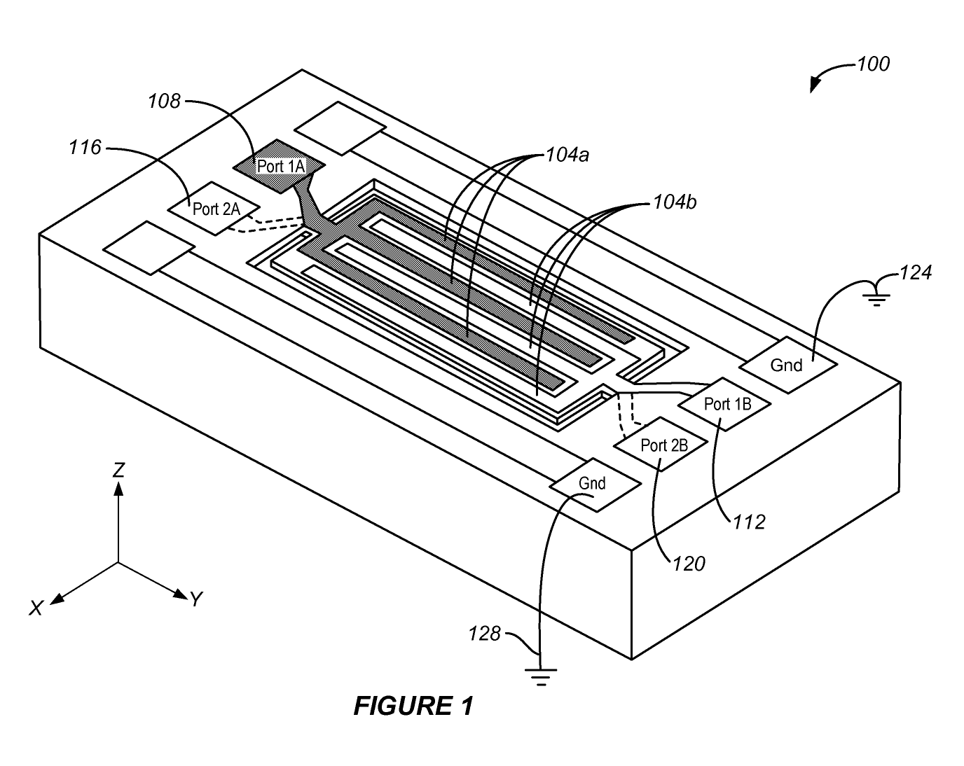

FIG. 1 shows an example of a perspective view of a CMR device. In FIG. 1, a CMR structure 100 includes an upper conductive layer of electrodes 104a and 104b. The first electrodes 104a are connected to a first input port 108, referred to as “Port 1A.” The second electrodes 104b are connected to a first output port 112, referred to as “Port 1B.” A lower conductive layer of electrodes is situated underneath the upper conductive layer on the opposite side of a sandwiched piezoelectric layer, as described below. In one example, the lower conductive layer includes a similar arrangement of first electrodes underlying the first electrodes 104a of the upper conductive layer and connected to a port 116, referred to as “Port 2A,” and a similar arrangement of second electrodes underlying the second electrodes 104b of the upper conductive layer and connected to a port 120, referred to as “Port 2B.” In some implementations, port 116 is configured as a second input port, while port 120 is configured as a second output port. In some other implementations, port 116 serves as the second output port, and port 120 serves as the second input port.

In FIG. 1, as further described below, the ports 108, 112, 116 and 120 can have different configurations. For instance, Ports 2A and 2B can be coupled to ground terminal 124 and/or ground terminal 128, thus grounding the lower conductive layer of electrodes, while an input electrical signal can be provided to Port 1A, resulting in an output electrical signal being provided to port 1B. In another configuration, a first input signal can be provided to Port 1A, and a second input signal can be provided to Port 2A, responsive to which a first output signal can be delivered to Port 1B, and a second output signal can be delivered to Port 2B. The piezoelectric layer disposed between the upper conductive layer and the lower conductive layer translates the input signal(s) to mechanical vibration, which can then be translated to the output signal(s).

In the example of FIG. 1, the electrodes in the respective conductive layers have longitudinal axes substantially oriented along a Y axis, illustrated in FIG. 1. The X, Y and Z axes of FIG. 1 and additional figures described below are provided for reference and illustrative purposes only. In this example, the electrodes are generally straight along their longitudinal axes, although the electrodes can be curved, i.e., have arced contours, be angled, or have other geometries, depending on the desired implementation. Elongated electrodes having any of these various shapes are sometimes referred to herein as “fingers.”

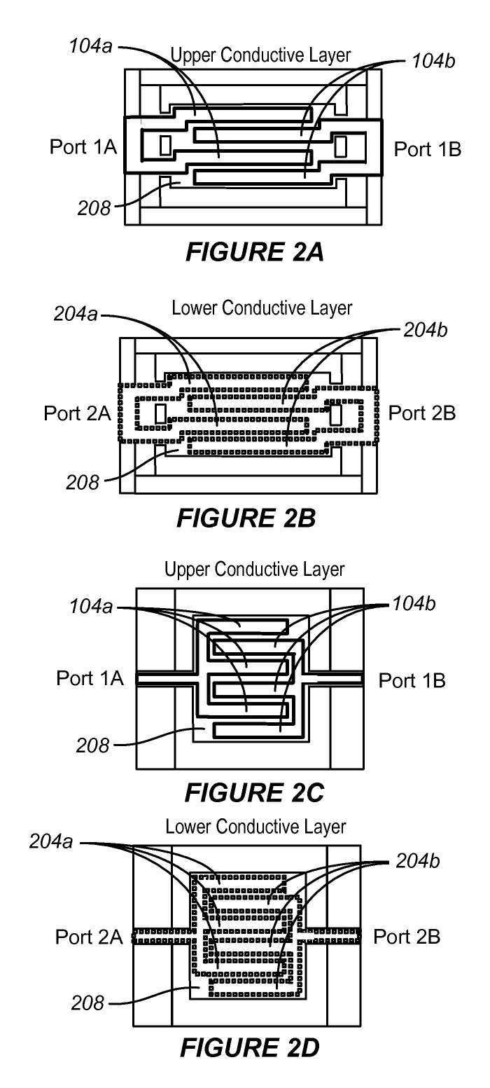

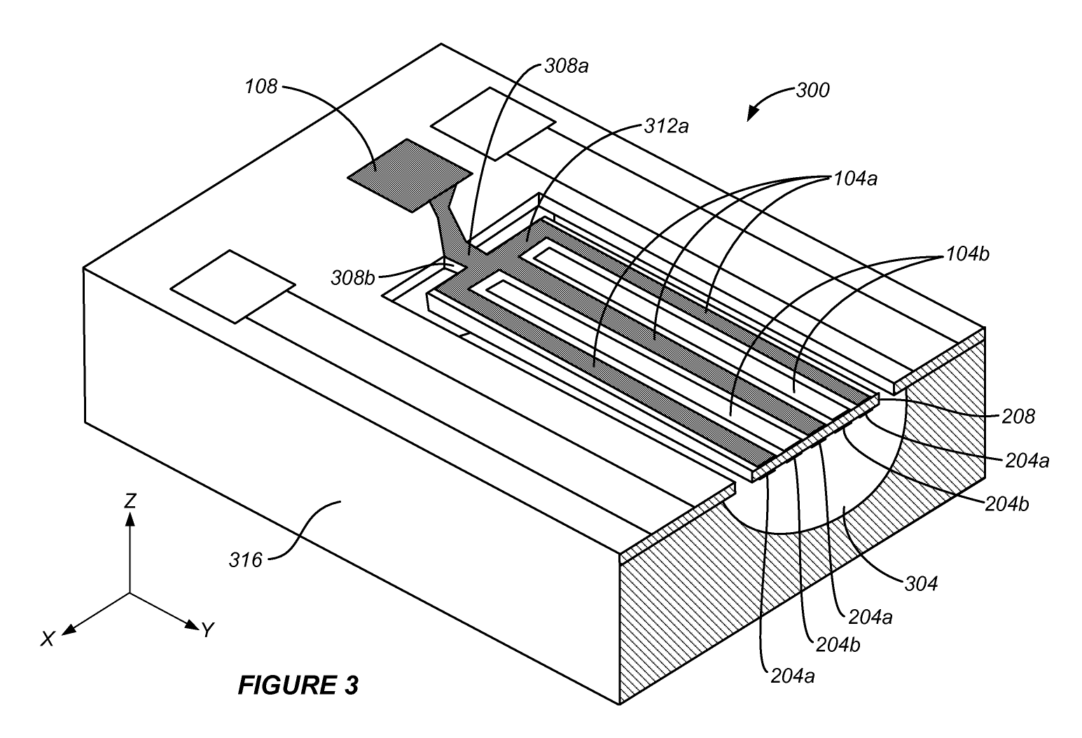

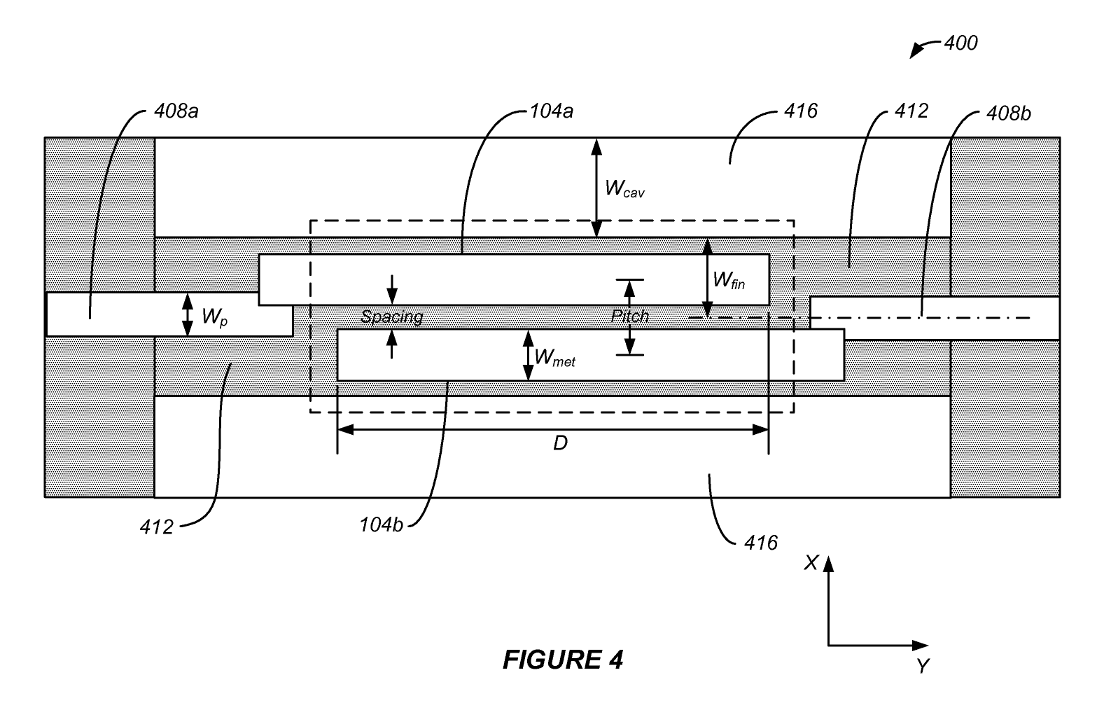

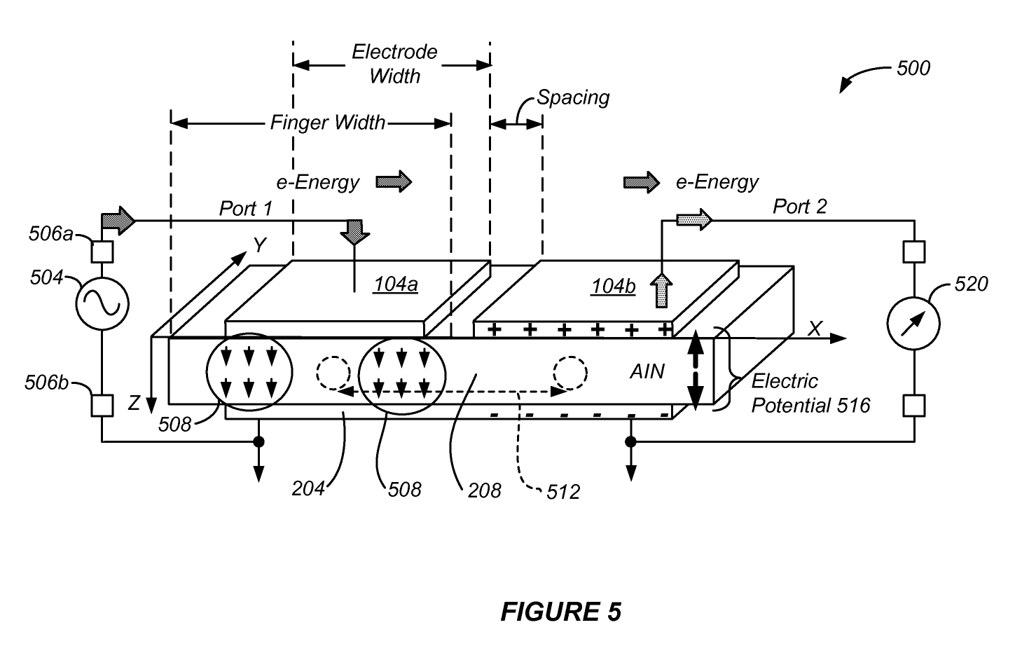

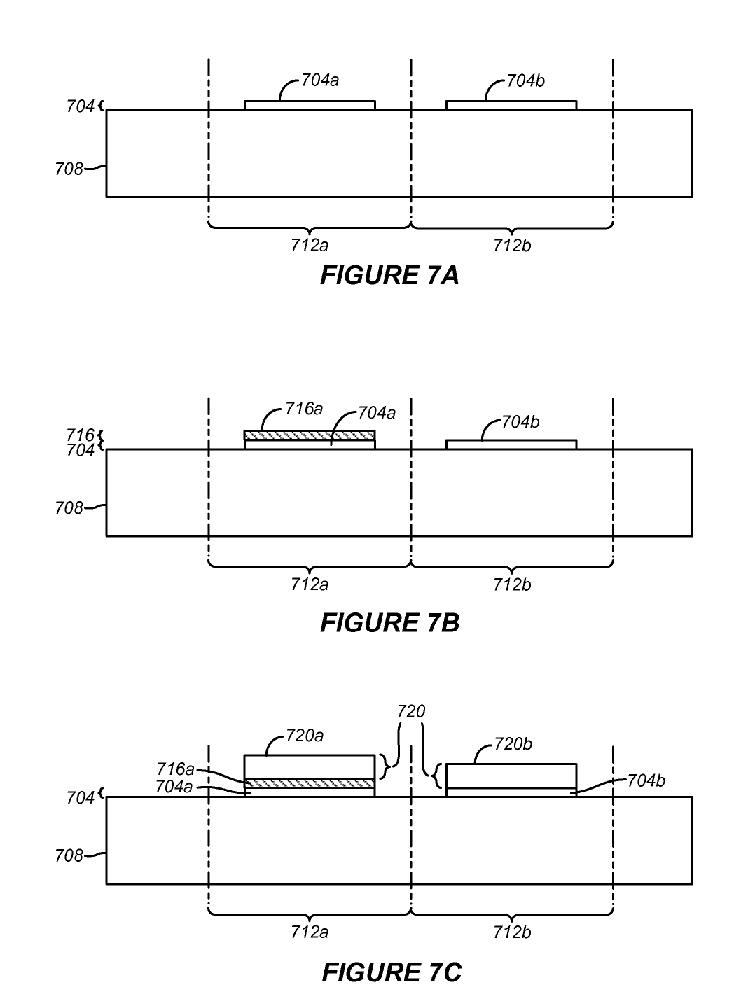

FIG. 2A shows an example of a top view of a CMR device. FIG. 2B shows an example of a bottom view of the CMR device of FIG. 2A. In FIG. 2A, two first electrodes 104a are interdigitated with two second electrodes 104b in the upper conductive layer, like the arrangement in FIG. 1. Unlike FIG. 1, in FIGS. 2A and 2B, each of the first electrodes 104a is connected to Port 1A by a respective connecting member, as further explained below with reference to FIG. 4. Separate connecting members are similarly incorporated to establish connections between respective second electrodes 104b and Port 1B. As shown in the bottom view of the CMR device in FIG. 2B, the lower conductive layer includes a corresponding arrangement of first electrodes 204a interdigitated with second electrodes 204b. In some examples, some or all of the first electrodes 104a and 204a of the respective conductive layers are aligned with one another, that is, along the Z axis of FIG. 1, while separated by piezoelectric layer 208. In such instances, the same can be true for the second electrodes 104b and 204b. In some other examples, some or all of the first electrodes 104a and 204a of the respective conductive layers are offset from one another along the Z axis of FIG. 1. For instance, second electrodes 204b can be underlying first electrodes 104a, while first electrodes 204a are underlying second electrodes 104b.

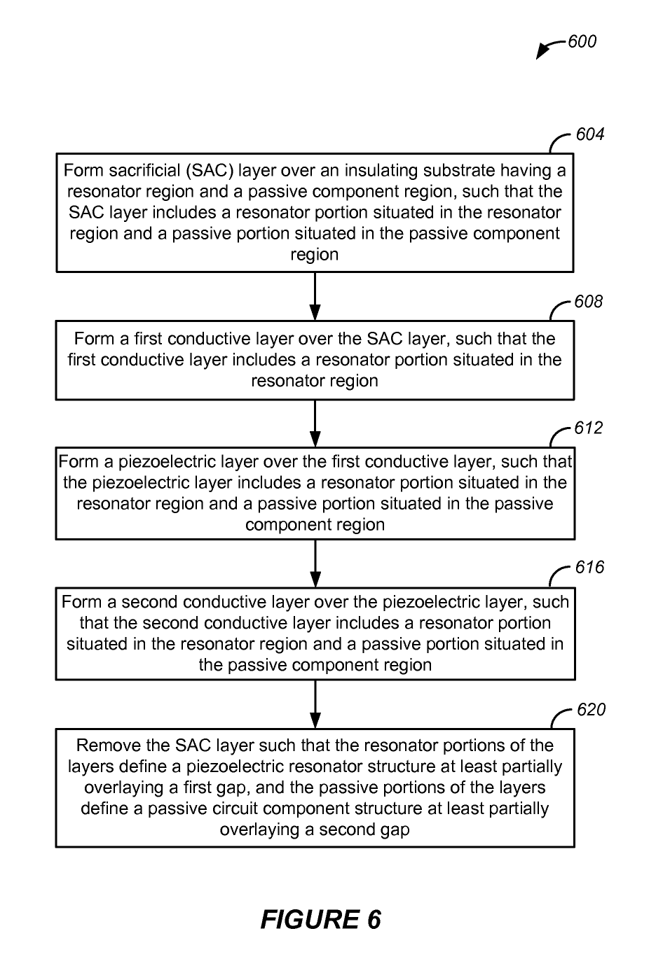

FIG. 2C shows an example of a top view of a CMR device. FIG. 2D shows an example of a bottom view of the CMR device of FIG. 2C. FIGS. 2C and 2D show that there can be additional first and second electrodes in the respective conductive layers, and the electrodes can have different lengths, widths, and spacings from those in FIGS. 2A and 2B. In the examples of FIGS. 2A-2D, the electrodes in the respective conductive layers are situated in a periodic arrangement and spaced apart from one another, for example, along the X axis of FIG. 1. Each set of electrodes 104a, 104b, 204a, and 204b, is connected to a respective port by a shared connecting member including tethers, as further explained below with reference to FIG. 3. In some examples, some or all of the first electrodes 104a and 204a of the respective conductive layers are aligned with one another, that is, along the Z axis of FIG. 1, while separated by piezoelectric layer 208. In such instances, the same can be true for the second electrodes 104b and 204b. In some other examples, some or all of the first electrodes 104a and 204a of the respective conductive layers are offset from one another along the Z axis of FIG. 1. For instance, second electrodes 204b can be underlying first electrodes 104a, while first electrodes 204a are underlying second electrodes 104b.

FIG. 3 shows an example of a perspective cross-sectional view of a CMR device. In FIG. 3, a resonator structure 300 includes an upper conductive layer of electrodes 104a and 104b, piezoelectric layer 208, and lower conductive layer of electrodes 204a and 204b, as described above. The resonator structure 300 is suspended in a cavity 304 by virtue of tethers 308a and 308b, as well as a matching pair of tethers (not shown) connected at the opposite end of the CMR. In FIG. 3, the tethers serve as physical anchors to hold the resonator structure in the cavity. The resonator structure is capable of lateral motion by virtue of vibration of the piezoelectric material, that is, with respect to a plane oriented along the X and Y axes. The tether 308a is electrically coupled between the first electrodes 104a of the upper conductive layer and port 108, while the tether 308b is electrically coupled between the underlying first electrodes 204a of the lower conductive layer and another port, such as port 116 of FIG. 1. The matching pair of tethers on the opposite end of the structure can similarly electrically couple second electrodes 104b and 204b of the upper and lower layers to their respective ports as described in the example of FIG. 1 above. The tethers can be fabricated as extensions of their respective conductive layers and can be on the order of several microns wide, e.g., along the X axis. In some implementations, the tethers 308a and 308b are designed such that their length, e.g., along the Y axis of FIG. 1, is an integer number of resonant quarter wavelengths.

In the examples shown in FIGS. 2C, 2D and FIG. 3, each set of electrodes has an interconnect electrically coupled to a respective tether. For instance, in FIG. 3, interconnect 312a is coupled between the first electrodes 104a and the tether 308a. Thus, in some implementations, the tether 308a, the electrically coupled interconnect 312a, and the first electrodes 104a form an integral part of the upper conductive layer. Another part of the upper conductive layer includes a corresponding tether and interconnect coupled to the second electrodes 104b. The resonator structure is partially surrounded by an opening in the form of the cavity 304 and is coupled to supporting structure including a substrate 316, which supports the resonator structure, by virtue of the tethers.

In FIGS. 1-3, the resonator structures can include a pattern of metal electrodes in the upper and lower conductive layers that, when provided one or more electrical input signals, causes the piezoelectric layer to have a motional response. The motional response can include a vibrational oscillation along one or more of the X, Y and Z axes. The resonant frequency response of the CMR structure can be controlled according to a periodic arrangement of electrodes in the conductive layers, for instance, by adjusting the width(s) as well as the spacing(s) of the electrodes from one another in a conductive layer, e.g., along the X axis of FIG. 1, as further explained below.

In FIGS. 1-3, the pattern of interdigitated first electrodes and second electrodes of a conductive layer is periodic in one direction, for instance, along the X axis of FIG. 1. As illustrated, the periodic arrangement of electrodes 104a and 104b includes alternating areas of metal, representing electrode regions, and space regions, i.e., areas without metal. Such space regions between the electrodes are also referred to herein as “spaces.” In various implementations, the areas of metal and the spaces have the same width, the areas of metal are wider than the spaces, the areas of metal are narrower than the spaces, or any other appropriate relation between the metal widths and spaces. The finger width of the CMR, a parameter based on a combination of electrode width and spacing, as described in greater detail below with reference to FIG. 4, can be adjusted to control one or more resonant frequencies of the structure. For instance, a first finger width in a conductive layer can correspond to a first resonant frequency of the CMR, and a second finger width in the conductive layer can provide a different second resonant frequency of the CMR.

The CMR structure can be driven into resonance by applying a harmonic electric potential that varies in time across the patterned conductive layers. The layout and interconnectivity of the periodic electrodes transduce the desired mode of vibration while suppressing the response of undesired spurious modes of vibration of the structure. For example, a specific higher order vibrational mode can be transduced without substantially transducing other modes. Compared to its response to a constant DC electric potential, the amplitude of the mechanical response of the resonator is multiplied by the Q factor (the typical Q factor is on the order of 500 to 5000). Engineering the total width of the resonator structure and the number of electrode periods provides control over the impedance of the resonator structure by scaling the amount of charge generated by the motion of the piezoelectric material.

FIG. 4 shows an example of a top view of a resonator device in accordance with one implementation. In the implementation of FIG. 4, a resonator structure 400 is configured as a CMR, with the electrodes in the respective conductive layers having longitudinal axes substantially parallel to one another and extending along the Y axis, as illustrated. A resonator structure generally has a finger width, Wfin, representing the width of each sub-resonator, which primarily includes one electrode and half of the width of the exposed piezoelectric material on either side of the one electrode along the X axis, for example, as shown in FIG. 4. The electrode width, that is, the width of an individual electrode, Wmet, is generally smaller than the finger width, to limit the feed-through capacitance between electrodes. The pitch of the resonator structure generally refers to the distance between mid-points of electrodes along the X axis, as shown in FIG. 4. The spacing of electrodes refers to the gap between the edges of adjacent electrodes along the X axis, as shown in FIG. 4. The resonant frequency of the resonator structures disclosed herein is primarily determined by the finger width or pitch. The electrode width and spacing have second-order effects on the frequency. The finger width and pitch are correlated with the electrode width and spacing parameters, by definition. Pitch is often equal to finger width, as shown in the example of FIG. 4.

In FIG. 4, in one example, the upper electrodes 104a and 104b have an electrode width along the X axis, Wmet, of 4.8 um. Connecting members 408a and 408b, which can include tethers in some examples, are coupled to the respective electrodes 104a and 104b. The connecting members 408a and 408b have a connecting member width, Wp, which can be smaller than Wmet in this example. In other instances, Wp is the same size or larger than Wmet, depending on the desired configuration. The finger width of the electrodes, Wfin, which corresponds to the half-width of the piezoelectric layer 412 in this example, is 6.4 um. Wcav, the cavity width of cavity 416 along the X axis can be an integer multiple of Wfin, such as 2*Wfin (e.g., 12.8 um) or other measurement. Thus, in this instance, Wcav is approximately the same as the full piezoelectric layer width. In this example, a distance D, in which the upper electrodes 104a and 104b are adjacent to one another, can be on the order of 128 um or 256 um, by way of example.

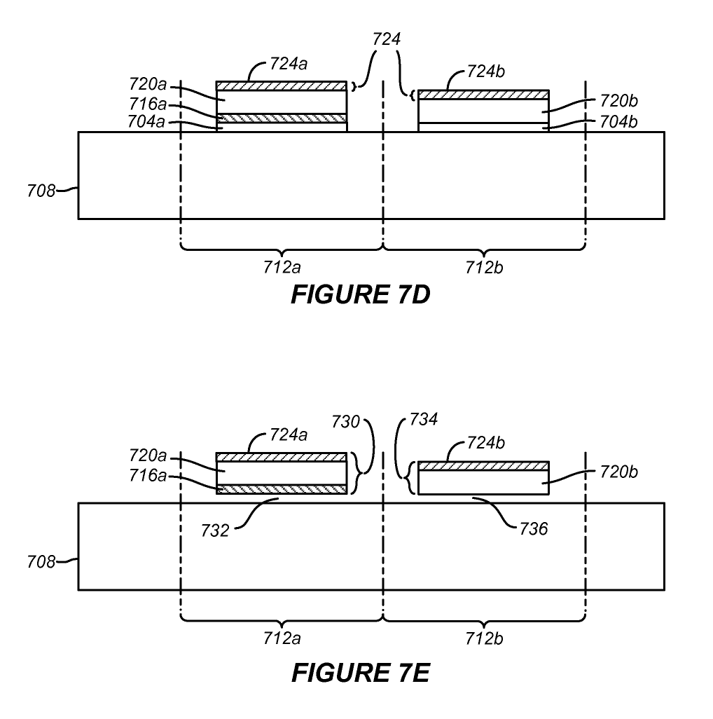

FIG. 5 shows an example of a perspective cross-sectional view of a resonator structure. In FIG. 5, the resonator structure 500 includes an upper conductive layer of electrodes 104a and 104b, a piezoelectric layer 208, and a lower conductive layer in the form of a single electrode 204, with the layers stacked as described above. In FIG. 5, there is an input port, “Port 1,” at which an input electrical signal can be delivered to first electrode 104a of the upper conductive layer. Port 1 can be coupled to receive the input electrical signal from various components, such as an amplifier or an antenna. In the illustration of FIG. 5, an alternating current (AC) voltage source 504 simulates the electrical signal delivered by such a component. The AC voltage source 504 has a first terminal 506a coupled to Port 1 and a second terminal 506b coupled to the lower electrode 204, which is coupled to ground in this example. In this way, an input AC signal can be provided from voltage source 504 to Port 1 and, hence, to first electrode 104a of the resonator. An electric field caused by the alternating voltage of the AC signal is applied across the thickness of the piezoelectric layer 208, illustrated by arrows 508 in FIG. 5. The thickness of the structure 500 is generally measured along the Z axis, and the length is measured along the Y axis, in the example of FIG. 5. The total width, referring to the width of the overall structure 500, as well as finger width, spacing, and electrode width are measured along the X axis, in the example of FIG. 5. The electric field 508 is applied in a manner to transduce mechanical resonance such that piezoelectric layer 208 experiences displacement back and forth along the X, Y and Z axes. This includes lateral displacement, that is, back and forth along the width and length of the structure, in this example, substantially along the respective X and Y axes of FIG. 5.

FIG. 5 illustrates a two-port structure with the second electrode 104b coupled to Port 2, which represents an output port in this configuration. Some of the present CMR implementations leverage the lateral movement substantially back-and-forth along the width of the structure (X axis) as illustrated by arrows 512, although the transduction of energy in some other implementations can be based on movement along the length and/or thickness of the structure. The piezoelectric layer 208 of the disclosed resonators can vibrate and move in all dimensions at resonant frequencies, for instances, in planes oriented along the X and Y axes, X and Z axes, and Y and Z axes. In one example of a CMR, the electric field 508 is induced across piezoelectric layer 208 along the Z axis, causing extensional mechanical stress 512 in the piezoelectric layer along the width of the structure through piezoelectric mechanical coupling. This mechanical energy causes an electric potential 516 to be generated across second electrode 104b and lower electrode 204. This transduced potential is sensed as an output electrical signal at Port 2 and can be measured by one or more sensors 520 coupled between Port 2 and the grounded lower electrode 204.

The fundamental frequency for the displacement of the piezoelectric layer can be set in part lithographically by the planar dimensions of the upper electrodes, the lower electrode(s), and/or the piezoelectric layer. For instance, the resonator structures described above can be implemented by patterning the input electrodes and output electrodes of a respective conductive layer symmetrically, as illustrated in FIGS. 1-4. In the examples of FIGS. 1-4, an AC electric field applied across the upper and lower electrodes induces mechanical deformations in one or more planes of the piezoelectric layer via the d31 or d33 coefficient of the piezoelectric material, such as AlN. At the device resonant frequency, the electrical signal across the device is reinforced and the device behaves as an electronic resonant circuit.

In the present implementations, the resonant frequency of a CMR can be directly controlled by setting the finger width, as shown in FIG. 5. One benefit of such a control parameter is that multi-frequency filters can be fabricated on the same chip. CMR 500 has a resonant frequency associated with the finger width, which is based on the spacing in combination with the electrode width of electrodes 104a and 104b, that is, along the X axis. The finger width in a conductive layer of the CMR structure can be altered to adjust the resonant frequency. For instance, the resonant frequency is generally lowered as the finger width increases, and vice versa.

The total width, length, and thickness of the resonator structure are parameters that also can be designated to optimize performance. In some CMR implementations, the finger width of the resonator is the main parameter that is controlled to adjust the resonant frequency of the structure, while the total width multiplied by the total length of the resonator (total area) can be set to control the impedance of the resonator structure. In one example, in FIG. 5, the lateral dimensions, i.e., the width and length of resonator structure 500 can be on the order of several 100 microns by several 100 microns for a device designed to operate around 1 GHz. In another example, the lateral dimensions are several 1000 microns by several 1000 microns for a device designed to operate at around 10 MHz. A suitable thickness of the piezoelectric layer can be about 0.01 to 10 microns thick.

The pass band frequency can be determined by the layout of the resonator structure, as can the terminal impedance. For instance, by changing the shape, size and number of electrodes, the terminal impedance can be adjusted. In some examples, longer fingers along the Y axis of FIGS. 1, 4 and 5 yield smaller impedance. This, in turn, is inversely proportional to the capacitance of the CMR. The resonant frequencies of the CMR structures described herein are generally insensitive to the fabrication process, to the extent that the piezoelectric thickness and thicknesses of the conductive layers do not significantly impact the frequency. The impedance and the frequency can be controlled independently, since the length and the width/spacing of electrodes are in perpendicular directions.

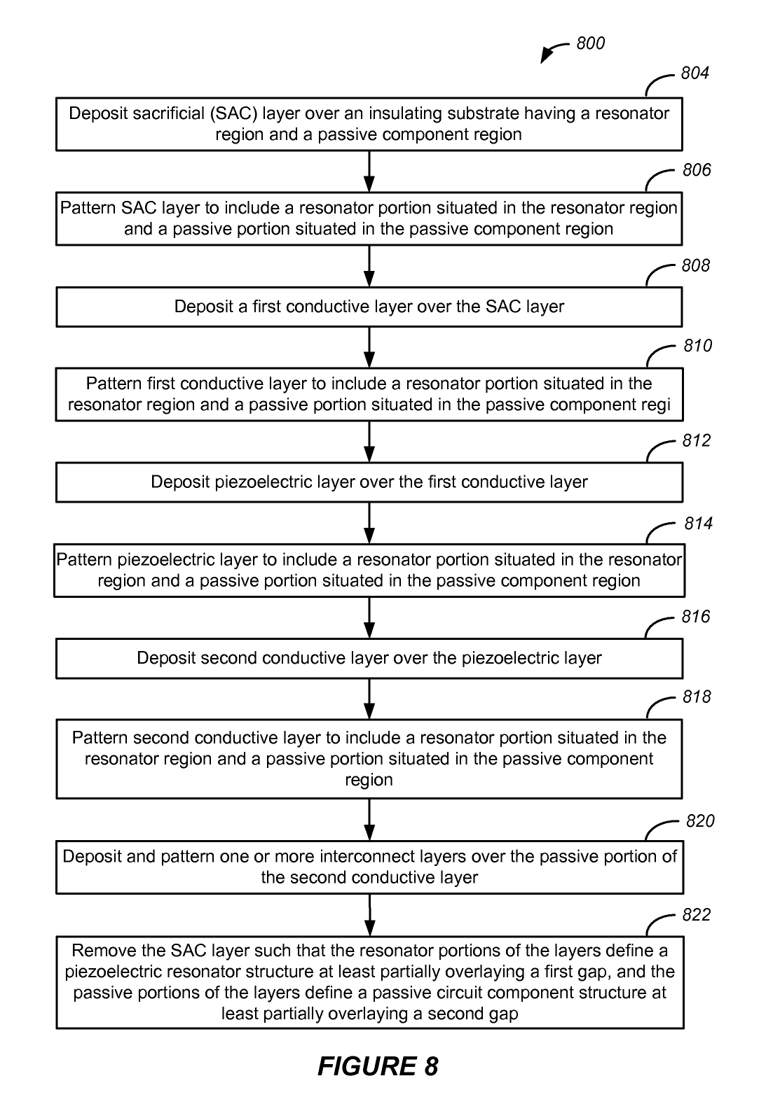

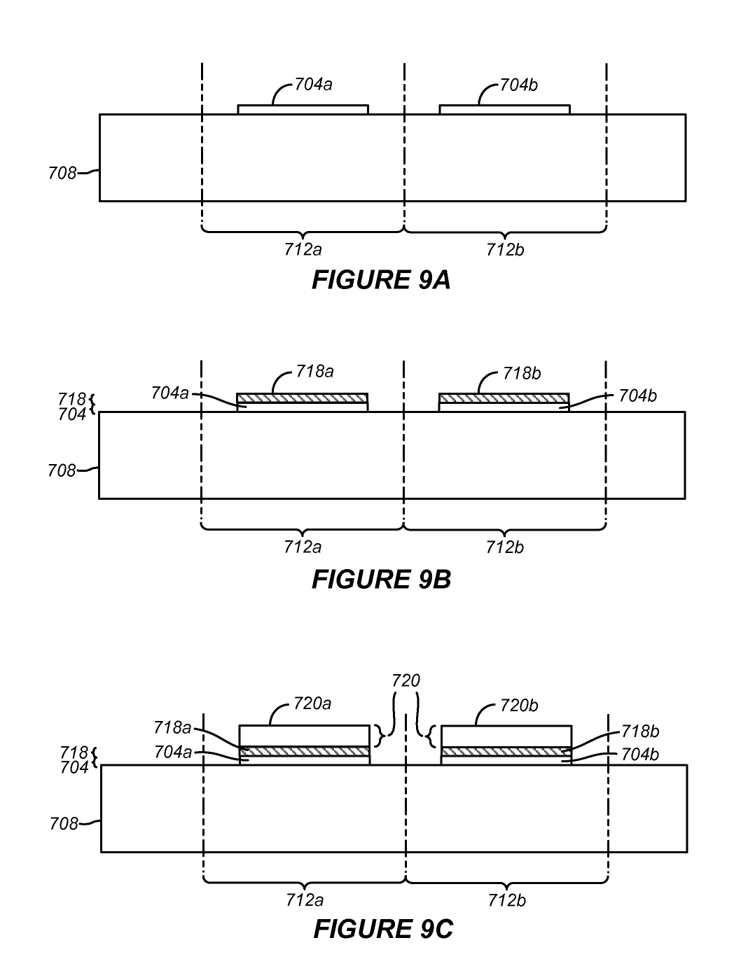

FIG. 6 shows an example of a flow diagram illustrating a process for forming a combined resonator and passive circuit component device. FIGS. 7A-7E show examples of cross-sectional schematic illustrations of stages of combined resonator and passive circuit component device fabrication in accordance with a process, for instance, as represented in FIG. 6. In FIG. 6, the process 600 begins in block 604 in which a sacrificial (SAC) layer 704 is formed over a substrate 708, such as an insulating substrate, having a resonator region 712a and a passive component region 712b, as shown in FIG. 7A. The SAC layer 704 includes a resonator portion 704a situated in the resonator region 712a and a passive portion 704b situated in the passive component region 712b. The SAC layer 704 can have various dimensions. In some implementations of the process 600, a suitable thickness of SAC layer 704 is in the range of about 0.5 micrometers (um) to 3 um. The SAC layer portions 704a and 704b define areas in which gaps such as air cavities will be formed to substantially isolate the resulting resonator structure and passive component structure(s) from the shared substrate 708, as further described below. The SAC layer 704 can be formed of silicon oxynitride (SiON), silicon oxide (SiOx), molybdenum (Mo), germanium (Ge), amorphous silicon (a-Si), poly-crystalline silicon, and/or various polymers, by way of example. In one example, SAC layer 704 is formed of Mo and has a thickness of about 0.5 um.

In block 608 of FIG. 6, a first conductive layer 716 is formed over the SAC layer 704, as shown in FIG. 7B. The first conductive layer 716 includes a resonator portion 716a situated in the resonator region 712a. The first conductive layer 716 is made of a conductive material such as metal and can be patterned to define one or more electrodes of a resonator as described above, depending on the desired configuration. When more than one electrode is defined, the electrodes can be connected at separate ports of the resonator device. Conductive layers as disclosed herein can be formed of Mo, platinum (Pt), aluminum (Al), Al/titanium nitride (Al/TiN), aluminum copper (AlCu), and other appropriate materials, and have various thicknesses depending on the desired implementation. For instance, the first conductive layer 716 can be deposited as a bi-layer with a metal such as Mo deposited on top of a seed layer such as AlN. Other suitable materials for a conductive layer include aluminum silicon (AlSi), AlCu, Ti, TiN, nickel (Ni), tungsten (W), ruthenium (Ru), and combinations thereof.

In block 612 of FIG. 6, a piezoelectric layer 720 is formed over the first conductive layer 716, as shown in FIG. 7C, such that the piezoelectric layer 720 includes a resonator portion 720a situated in the resonator region 712a and a passive portion 720b situated in the passive component region 712b. In block 616 of FIG. 6, a second conductive layer 724 is formed over the piezoelectric layer 720, such that the second conductive layer 724 includes a resonator portion 724a situated in the resonator region 712a and a passive portion 724b situated in the passive component region 712b, as shown in FIG. 7D. The second conductive layer portion 724a also can be patterned to define one or more electrodes, as explained above with respect to first conductive layer 716. In some implementations, overlaying groups of electrodes can be defined in the first and second conductive layers in the resonator region 712a on opposite surfaces of the piezoelectric layer 720, as explained above with respect to FIGS. 1-5. The second conductive layer 724 can be formed of AlCu, for example, as well as other materials described above. In one example, the second conductive layer 724 has a thickness of about 2000 Angstroms. Other suitable thicknesses range from about 0.1 um to 0.3 um.

In block 620 of FIG. 6, the SAC layer 704 is removed. The resonator portions of the remaining layers define a piezoelectric resonator structure 730, as shown in FIG. 7E. This structure 730 at least partially overlays a first gap 732 defined by removal of SAC layer portion 704a. The passive portions of the remaining layers define a passive circuit component structure 734, which at least partially overlays a second gap 736 defined by removal of SAC layer portion 704b. In some implementations, the SAC layer 704 is released by exposing the structure to XeF₂ gas or SF₆ plasma, for instance, when the SAC layer 704 is formed of Mo or a-Si. Hydrofluoric acid (HF) can be used when the SAC layer 704 is formed of SiON or SiOx. The gaps 732 and 736 are essentially defined by the absence of the SAC layer 704. Release of the SAC layer can provide low loss and high Q of the passive component structure, for instance, when the structure is an inductor or capacitor, since any loss otherwise caused by the substrate can be minimized.

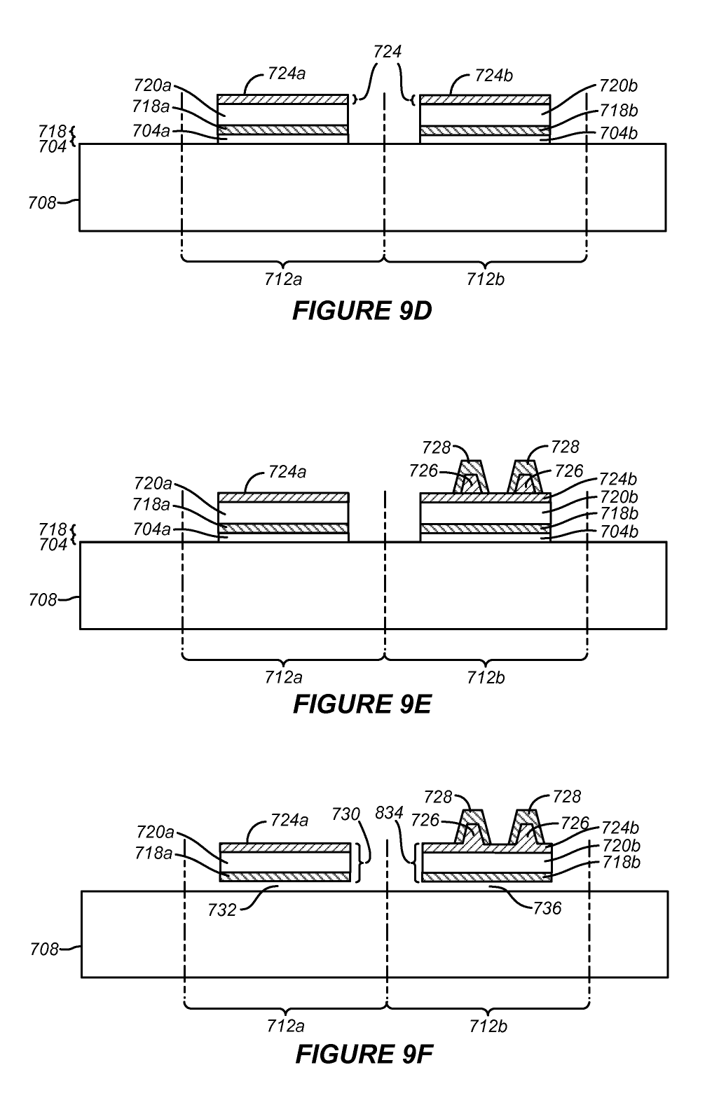

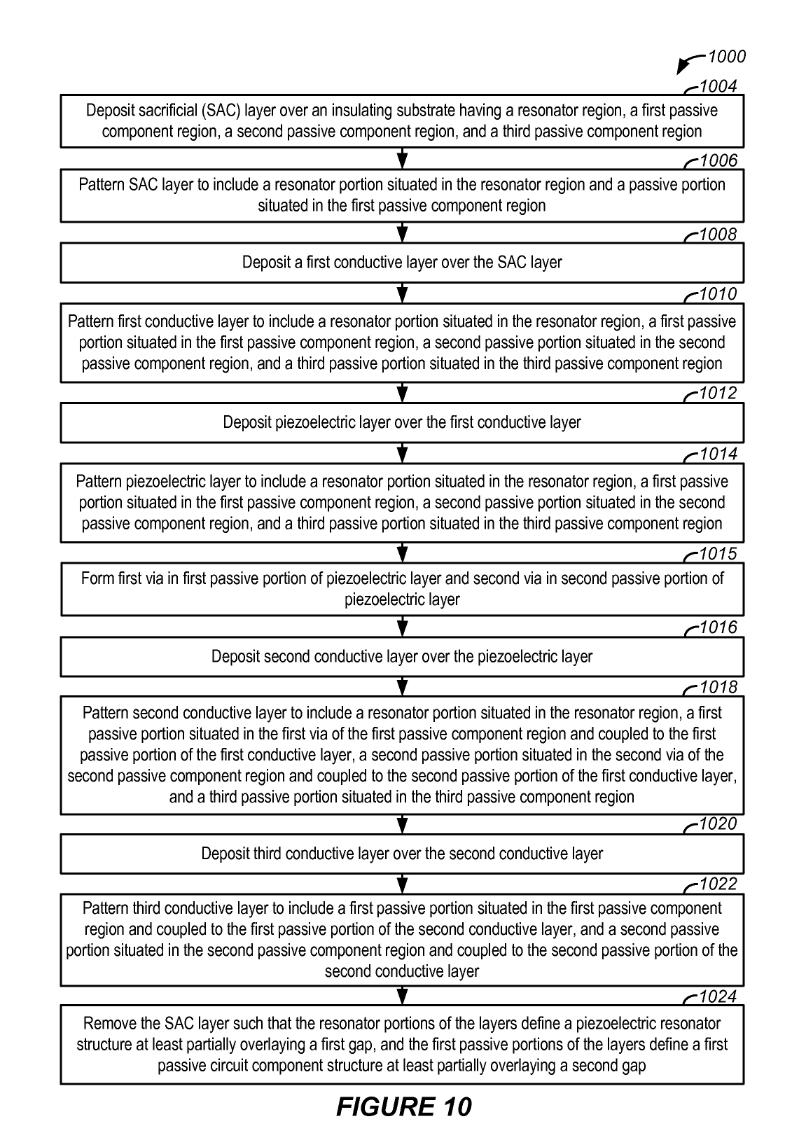

FIG. 8 shows an example of a flow diagram illustrating a process for forming a combined resonator and passive circuit component device. FIGS. 9A-9F show examples of cross-sectional schematic illustrations of stages of combined resonator and passive circuit component device fabrication in accordance with a process, for instance, as represented in FIG. 8. In FIG. 8, the process 800 begins in block 804 in which SAC layer 704 is deposited over a substrate 708 having a resonator region 712a and a passive component region 712b. The SAC layer 704 is then patterned in block 806, for instance, using an appropriately shaped and aligned mask, to define a resonator portion 704a situated in the resonator region 712a and a separate passive portion 704b situated in the passive component region 712b, as shown in FIG. 9A.

In block 808 of FIG. 8, a first conductive layer 718 is deposited over SAC layer 704 and patterned in block 810 to define a resonator portion 718a situated in the resonator region 712a and a passive portion 718b situated in the passive component region 712b, as shown in FIG. 9B. Thus, in some examples, separate resonator and passive portions can be formed from a shared first conductive layer 718. In some implementations, before depositing the first conductive layer 718, a post oxide layer can be deposited and patterned over the respective SAC layer portions 704a and 704b and adjacent exposed surfaces of the substrate 708. In particular, such a post oxide layer can be patterned to expose an area of each SAC layer portion 704a and 704b, while defining anchor structures on sides of the respective SAC layer portions 704a and 704b. These anchors can serve to isolate the resulting resonator structure and passive component(s) and hold them to the substrate when the SAC layer is released. Such a post oxide layer can be formed of materials such as SiOx and SiON and have a thickness, for example, on the order of about 1 um to 3 um. In some other implementations, the post oxide layer can be formed of nickel silicide (NiSi) or molybdenum silicide (MoSi₂). In some examples, such a post oxide layer is about 0.5 um, or can be thicker, such as in the range of about 0.5 um to 5 um.

In block 810 of FIG. 8, the resonator portion 718a of the first conductive layer 718 can be patterned using, for instance, an appropriate mask to define one or more lower electrodes. In some implementations, the one or more lower electrodes can be shaped to match overlaying upper electrodes. In the example of FIG. 9B, resonator portion 718a is formed to have a single electrode in the shape of a strip, which extends laterally across the SAC layer portion 704a.

In block 812 of FIG. 8, piezoelectric layer 720 is deposited over the first conductive layer 718 and patterned in block 814, as shown in FIG. 9C, such that the piezoelectric layer 720 includes a resonator portion 720a situated in the resonator region 712a and a passive portion 720b situated in the passive component region 712b. The piezoelectric layer can be formed of AlN and have a thickness, for example, between about 1 um and 2 um.

In block 816 of FIG. 8, a second conductive layer 724 is deposited over the piezoelectric layer 720 and patterned in block 818 to include a resonator portion 724a situated in the resonator region 712a and a passive portion 724b situated in the passive component region 712b, as shown in FIG. 9D. In block 820 of FIG. 8, first and second interconnect layers 726 and 728 are deposited over the passive portion of the second conductive layer and patterned as shown in FIG. 9E. In this example, the first interconnect layer 726 is thicker than individual conductive layers described above. For instance, the first interconnect layer 726 can be about 5 um thick, whereas other thicknesses, such as greater than about 5 um thick can be used in some examples. The first interconnect layer 726 is in contact with a passive portion 724b of the second conductive layer 724 and covers a portion of a top surface of the passive portion 724b. The second interconnect layer 728 coats exposed surfaces of the first interconnect layer 724. Thus, the first and second interconnect layers 726 and 728 cooperate to define an integral conductive layer for interconnections with any of various electrical components and circuits, including the resonator in region 712a. Interconnect layers can be formed of metal and coupled to define transmission lines to one or more conductive layer portions of the passive component defined in region 712b, as desired for the particular circuit implementation. AlSi, AlCu, plated Cu, or other appropriate materials can be used to form the interconnect layer(s).

In block 822 of FIG. 8, the SAC layer 704 is removed such that the resonator portions of the remaining layers define piezoelectric resonator structure 730, as shown in FIG. 9F. This structure 730 at least partially overlays a first gap 732 defined by removal of SAC layer portion 704a. The passive portions of the remaining layers define a passive circuit component structure 834, such as a capacitor or an inductor, that at least partially overlays a second gap 736 defined by removal of the SAC layer portion 704b.

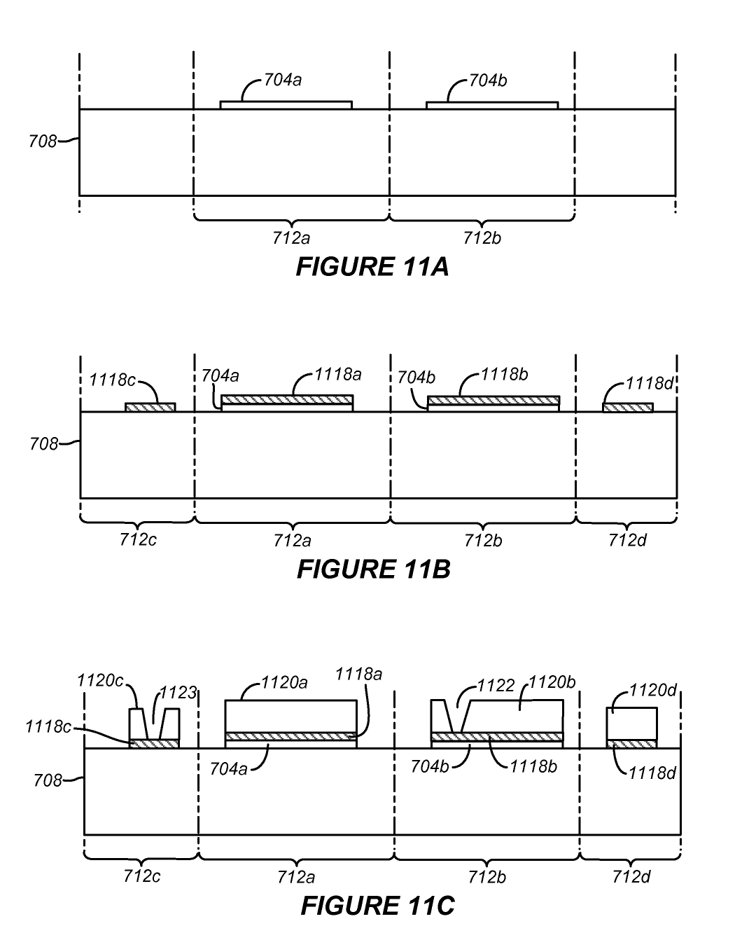

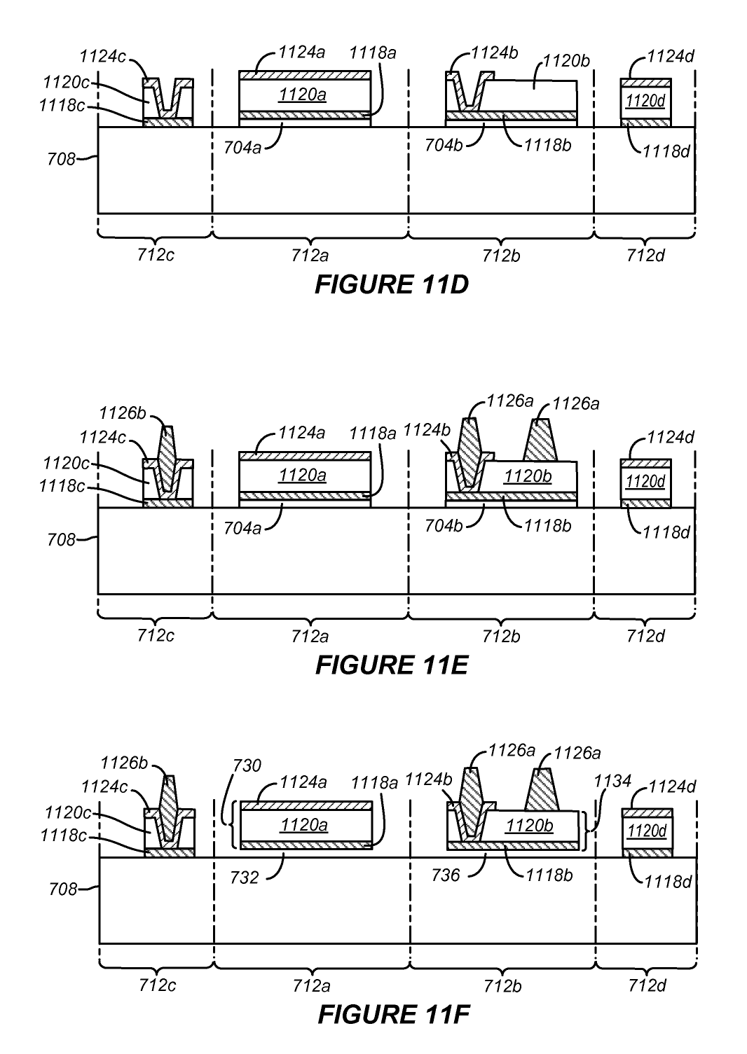

FIG. 10 shows an example of a flow diagram illustrating a process for forming a combined resonator and passive circuit component device. FIGS. 11A-11F show examples of cross-sectional schematic illustrations of stages of combined resonator and passive circuit component device fabrication in accordance with a process, for instance, as represented in FIG. 10. In FIG. 10, the process 1000 begins in blocks 1004 and 1006 in which a SAC layer 704 is deposited over a substrate 708 and patterned in a resonator region 712a and a passive component region 712b, as described above, and as shown in FIG. 11A. In block 1008 of FIG. 10, a first conductive layer 1118 is deposited over SAC layer 704, as shown in FIG. 11B. In this example, in block 1010, a first conductive layer 1118 is patterned to define a resonator portion 1118a situated in the resonator region 712a, a first passive portion 1118b situated in the first passive component region 712b, a second passive portion 1118c situated in a second passive component region 712c, and a third passive portion 1118d situated in a third passive component region 712d, as shown in FIG. 11B.

In block 1012 of FIG. 10, a piezoelectric layer 1120 is deposited over the first conductive layer 1118. In block 1014, as shown in FIG. 11C, the piezoelectric layer 1120 is patterned to include a resonator portion 1120a situated in the resonator region 712a and a first passive portion 1120b situated in the first passive component region 712b. In this example, the patterned piezoelectric layer 1120 also includes a second passive portion 1120c situated in the second passive component region 712c, and a third passive portion 1120d situated in the third passive component region 712d. In block 1015, a first via 1122 is formed in the first passive portion 1120b, for instance, by etching, to partially expose a top surface of first passive portion 1118b of the first conductive layer. Similarly, a second via 1123 is formed in the second passive portion 1120c to partially expose a top surface of second passive portion 1118c of the first conductive layer.

In block 1016 of FIG. 10, a second conductive layer 1124 is deposited over the piezoelectric layer 1120. In block 1018, the second conductive layer 1124 is patterned to define a resonator portion 1124a situated in the resonator region 712a, a first passive portion 1124b situated in the first via 1122 of the first passive component region 712b and contacting the partially exposed top surface of first passive portion 1118b of the first conductive layer, a second passive portion 1124c situated in the second via 1123 of the second passive component region 712c and contacting the partially exposed top surface of second passive portion 1118c of the first conductive layer, and a third passive portion 1124d situated in the third passive component region 712d, as shown in FIG. 11D.

In block 1020 of FIG. 10, a third conductive layer 1126 is deposited over the second conductive layer 1124. In block 1022, as shown in FIG. 11E, the third conductive layer 1126 is patterned to include a first passive portion 1126a situated in the first passive component region 712b and in conductive contact with the first passive portion 1124b of the second conductive layer, and a second passive portion 1126b situated in the second passive component region 712c and coupled to the second passive portion 1124c of the second conductive layer. In block 1022 of FIG. 10, the SAC layer 704 is removed. The resonator portions of the remaining layers define a piezoelectric resonator structure 730, as shown in FIG. 11F. This structure 730 at least partially overlays a first gap 732 defined by removal of SAC layer portion 704a. The first passive portions of the remaining layers define a passive circuit component structure 1134, which at least partially overlays a second gap 736 defined by removal of SAC layer portion 704b. In some implementations, for instance, when the first passive component in region 712b is an inductor, the first passive portion 1126a is sufficiently thick to provide high Q and low resistivity. In such instances, the piezoelectric portion 1120b should generally be sufficiently thick to isolate the third conductive layer from the first conductive layer. When the piezoelectric layer is formed of AlN, thermal dissipation can be achieved in high power amplifier and other circuits incorporating the inductor.

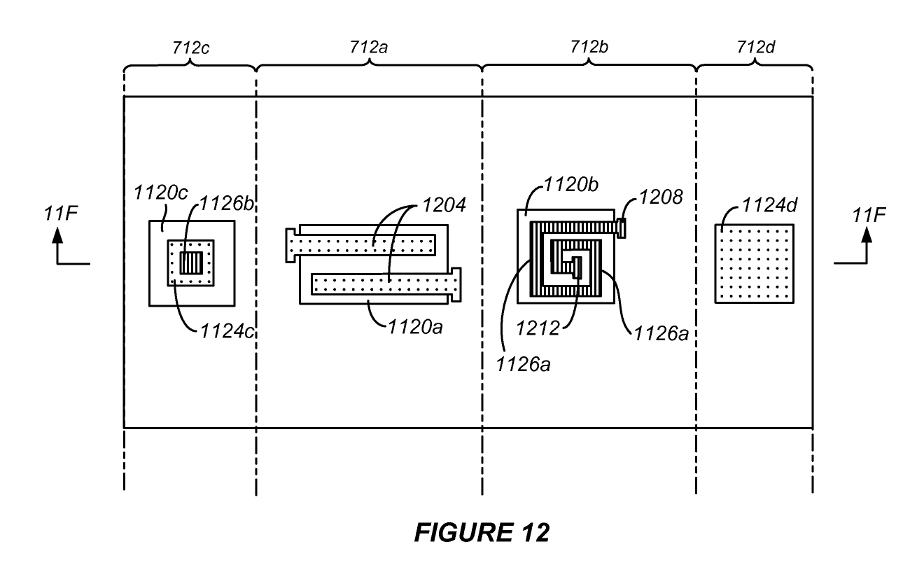

FIG. 12 shows an example of a top-down view of a combined resonator and passive circuit component device, for instance, as represented in FIG. 11F. The device of FIG. 12 represents one of many examples of the resulting device of the process of FIG. 10. In one example, the cross-sectional view of FIG. 11F is taken along lines 11F-11F of the device of FIG. 12. In FIG. 12, the resonator portion 1124a of the second conductive layer is patterned in the form of two or more elongated electrodes 1204 overlaying portion 1120a of the piezoelectric layer, to define a piezoelectric laterally vibrating resonator in region 712a.

The first passive portion 1126a of the third conductive layer is shaped in a spiral pattern as shown in FIG. 12, and includes a first terminal 1208 and a second terminal 1212. One of these terminals can be implemented in FIG. 11F as the first conductive layer portion 1118b coupled to the spiral pattern of portion 1126a of the third conductive layer by virtue of portion 1124b of the second conductive layer disposed in via 1122. The other terminal can be situated in the third conductive layer 1126 as generally shown in FIG. 11F. The resulting two-terminal device in region 712b is an inductor, in this example.

In FIG. 12, the conductive material of portions 1126b, 1124c, and 1118c in region 712c can serve as a resistor in some examples. The amount of conductive material in portions 1126b, 1124c and 1118c can be set to control the resistance of such a resistor. The resulting two-terminal device in region 712d is a capacitor in this example, with portion 1124d serving as a first conductive plate, piezoelectric portion 1120d serving as a dielectric layer, and portion 1118d serving as a second conductive plate.

In FIG. 11F and FIG. 12, additional portions of the above-described conductive layer(s) can be formed on substrate 708 to define electrodes for routing signals to the resonator and/or any of the passive circuit components. Such electrodes also can serve as conductive contacts with external circuitry or as probing pads for evaluation of circuit performance. For instance, the resistor structure in region 712c can serve as such an electrode, since the third conductive layer portion 1126b is coupled to the first conductive layer portion 1118c by virtue of second conductive layer portion 1124c in via 1123. Thus, inter-layer electrical connections can be realized for various circuit implementations.

The piezoelectric materials that can be used in fabrication of the piezoelectric layers of electromechanical systems resonators and dielectric layers of passive components disclosed herein include, for example, aluminum nitride (AlN), zinc oxide (ZnO), gallium arsenide (GaAs), aluminum gallium arsenide (AlGaAs), gallium nitride (GaN), quartz and other piezoelectric materials such as zinc-sulfide (ZnS), cadmium-sulfide (CdS), lithium tantalite (LiTaO3), lithium niobate (LiNbO3), lead zirconate titanate (PZT), members of the lead lanthanum zirconate titanate (PLZT) family, doped aluminum nitride (AlN:Sc), and combinations thereof. The conductive layers described above may be made of various conductive materials including platinum (Pt), aluminum (Al), molybdenum (Mo), tungsten (W), titanium (Ti), niobium (Nb), ruthenium (Ru), chromium (Cr), doped polycrystalline silicon, doped aluminum gallium arsenide (AlGaAs) compounds, gold (Au), copper (Cu), silver (Ag), tantalum (Ta), cobalt (Co), nickel (Ni), palladium (Pd), silicon germanium (SiGe), doped conductive zinc oxide (ZnO), and combinations thereof. In various implementations, the upper metal electrodes and/or the lower metal electrodes can include the same conductive material(s) or different conductive materials.

The description herein is directed to certain implementations for the purposes of describing the innovative aspects of this disclosure. However, a person having ordinary skill in the art will readily recognize that the teachings herein can be applied in a multitude of different ways. The described implementations may be implemented in any device or system that can be configured to display an image, whether in motion (e.g., video) or stationary (e.g., still image), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (i.e., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS), microelectromechanical systems (MEMS) and non-MEMS applications), aesthetic structures (e.g., display of images on a piece of jewelry) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

An example of a suitable electromechanical systems (EMS) or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the IMOD. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

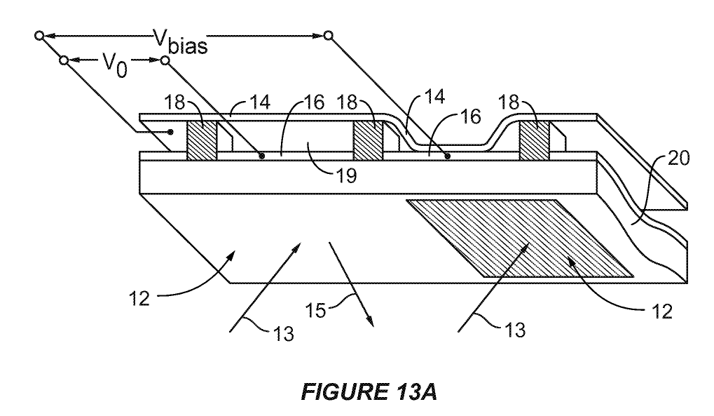

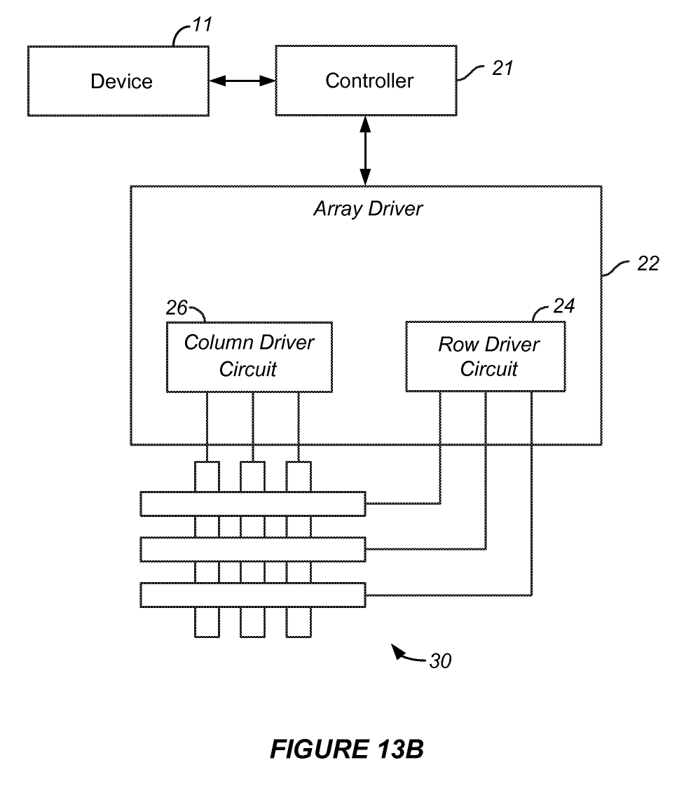

FIG. 13A shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 13A includes two adjacent IMODs 12. In the IMOD 12 on the left (as illustrated), a movable reflective layer 14 is illustrated in a relaxed position at a predetermined distance from an optical stack 16, which includes a partially reflective layer. The voltage V0 applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage Vbias applied across the IMOD 12 on the right is sufficient to maintain the movable reflective layer 14 in the actuated position.

In FIG. 13A, the reflective properties of pixels 12 are generally illustrated with arrows 13 indicating light incident upon the pixels 12, and light 15 reflecting from the IMOD 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the IMOD 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the separation between posts 18 may be approximately 1-1000 um, while the gap 19 may be less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the IMOD 12 on the left in FIG. 13A, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated IMOD 12 on the right in FIG. 13A. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 13B shows an example of a system block diagram illustrating an electronic device incorporating a 3×3 IMOD display. The electronic device of FIG. 13B represents one implementation in which a combined resonator and passive component(s) device 11 constructed in accordance with the implementations described above with respect to FIGS. 1-12 can be incorporated. The electronic device in which device 11 is incorporated may, for example, form part or all of any of the variety of electrical devices and electromechanical systems devices set forth above, including both display and non-display applications.

Here, the electronic device includes a controller 21, which may include one or more general purpose single- or multi-chip microprocessors such as an ARM®, Pentium®, 8051, MIPS®, Power PC®, or ALPHA®, or special purpose microprocessors such as a digital signal processor, microcontroller, or a programmable gate array. Controller 21 may be configured to execute one or more software modules. In addition to executing an operating system, the controller 21 may be configured to execute one or more software applications, including a web browser, a telephone application, an email program, or any other software application.

The controller 21 is configured to communicate with device 11. The controller 21 also can be configured to communicate with an array driver 22. The array driver 22 can include a row driver circuit 24 and a column driver circuit 26 that provide signals to, e.g., a display array or panel 30. Although FIG. 13B illustrates a 3×3 array of IMODs for the sake of clarity, the display array 30 may contain a very large number of IMODs, and may have a different number of IMODs in rows than in columns, and vice versa. Controller 21 and array driver 22 may sometimes be referred to herein as being “logic devices” and/or part of a “logic system.”

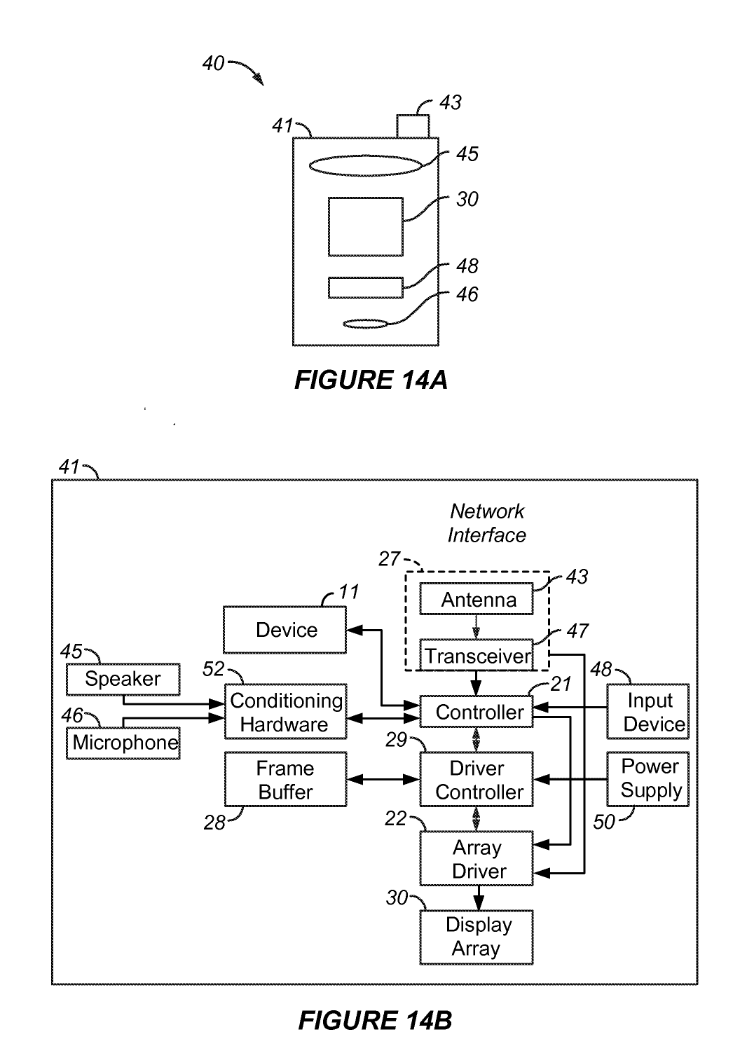

FIGS. 14A and 14B show examples of system block diagrams illustrating a display device 40 that includes a plurality of IMODs. The display device 40 can be, for example, a smart phone, a cellular or mobile telephone. However, the same components of the display device 40 or slight variations thereof are also illustrative of various types of display devices such as televisions, tablets, e-readers, hand-held devices and portable media players.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an IMOD display, as described herein.

The components of the display device 40 are schematically illustrated in FIG. 20B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (such as an IMOD controller). Additionally, the array driver 22 can be a conventional driver or a bi-stable display driver (such as an IMOD display driver). Moreover, the display array 30 can be a conventional display array or a bi-stable display array (such as a display including an array of IMODs). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A process for forming a combined resonator and passive circuit component device, comprising:
forming a sacrificial (SAC) layer over an insulating substrate having a resonator region and a passive component region, the SAC layer including a resonator portion situated in the resonator region and a passive portion situated in the passive component region;
forming a first conductive layer over the SAC layer, the first conductive layer including a resonator portion situated in the resonator region;
forming a piezoelectric layer over the first conductive layer, the piezoelectric layer including a resonator portion situated in the resonator region and a passive portion situated in the passive component region;
forming a second conductive layer over the piezoelectric layer, the second conductive layer including a resonator portion situated in the resonator region and a passive portion situated in the passive component region; and
removing the SAC layer to define a first gap and a second gap;
the resonator portions of the layers defining a piezoelectric resonator structure at least partially overlaying the first gap, the passive portions of the layers defining a passive circuit component structure at least partially overlaying the second gap.

2. The process of claim 1, wherein the first conductive layer further includes a passive portion situated in the passive component region.

3. The process of claim 1, further comprising:
forming one or more interconnect layers over the passive portion of the second conductive layer.

4. The process of claim 3, wherein the one or more interconnect layers include one or more first conductive contacts coupled to the passive component structure.

5. The process of claim 4, wherein the one or more interconnect layers further include one or more second conductive contacts coupled to the piezoelectric resonator structure.

6. The process of claim 1, wherein the SAC layer is formed of at least one of amorphous silicon or molybdenum.

7. The process of claim 1, wherein the piezoelectric layer is formed of at least one piezoelectric material selected from the group consisting of: aluminum nitride, zinc oxide, gallium arsenide, aluminum gallium arsenide, gallium nitride, quartz, zinc-sulfide, cadmium-sulfide, lithium tantalate, lithium niobate, and lead zirconate titanate.

8. The process of claim 1, wherein the passive circuit component structure is at least one of an inductor and a capacitor.

9. A process for forming a combined resonator and passive circuit component device, comprising:
forming a sacrificial (SAC) layer over a substrate having a resonator region, a first passive component region, a second passive component region, and a third passive component region, the SAC layer including a resonator portion situated in the resonator region and a passive portion situated in the first passive component region;
forming a first conductive layer over the SAC layer, the first conductive layer including a resonator portion situated in the resonator region, a first passive portion situated in the first passive component region, a second passive portion situated in the second passive component region, and a third passive portion situated in the third passive component region;
forming a piezoelectric layer over the first conductive layer, the piezoelectric layer including a resonator portion situated in the resonator region, a first passive portion situated in the first passive component region, a second passive portion situated in the second passive component region, and a third passive portion situated in the third passive component region;
forming a first via in the first passive component region of the piezoelectric layer and a second via in the second passive component region of piezoelectric layer;
forming a second conductive layer over the piezoelectric layer, the second conductive layer including a resonator portion situated in the resonator region, a first passive portion situated in the first via of the first passive component region and coupled to the first passive portion of the first conductive layer, a second passive portion situated in the second via of the second passive component region and coupled to the second passive portion of the first conductive layer, and a third passive portion situated in the third passive component region;
forming a third conductive layer over the second conductive layer, the third conductive layer including a first passive portion situated in the first passive component region and coupled to the first passive portion of the second conductive layer, and a second passive portion situated in the second passive component region and coupled to the second passive portion of the second conductive layer; and
removing the SAC layer to define a first gap and a second gap;
the resonator portions of the layers defining a piezoelectric resonator structure at least partially overlaying the first gap, the first passive portions of the layers defining a first passive circuit component structure at least partially overlaying the second gap, the second passive portions of the layers defining a second passive circuit component structure, and the third passive portions of the layers defining a third passive circuit component structure.

10. The process of claim 9, wherein the first passive portion of the third conductive layer has a spiral shape.

11. The process of claim 9, wherein the first passive circuit component structure is an inductor, the second passive circuit component structure is a resistor, and the third passive circuit component structure is a capacitor.

12. The process of claim 9, wherein the SAC layer is formed of at least one of amorphous silicon or molybdenum.

13. A combined resonator and passive circuit component device comprising:
a piezoelectric resonator structure formed over an insulating substrate, a portion of the piezoelectric resonator structure spaced apart from the substrate by a first gap; and
a passive circuit component structure formed over the insulating substrate, a portion of the passive circuit component structure spaced apart from the substrate by a second gap;
the first gap and the second gap defined by removal of a sacrificial (SAC) layer.

14. The device of claim 13, wherein the piezoelectric resonator structure and the passive circuit component structure include a shared piezoelectric layer.

15. The device of claim 13, wherein the piezoelectric resonator structure and the passive circuit component structure include one or more shared conductive layers.

16. The device of claim 13, wherein the piezoelectric resonator structure and the passive circuit component structure include a shared interconnect layer.

17. The device of claim 13, wherein the passive circuit component structure is at least one of a capacitor or an inductor.

18. The device of claim 13, wherein the insulating substrate is formed of glass.

19. Apparatus comprising:
the device of claim 13;
a display;
a processor configured to communicate with the display, the processor being configured to process image data; and
a memory device configured to communicate with the processor.

20. The apparatus of claim 19 further comprising:
a driver circuit configured to send at least one signal to the display; and
a controller configured to send at least a portion of the image data to the driver circuit.

21. The apparatus of claim 19, wherein one or more electrodes of the piezoelectric resonator structure is coupled to send the image data to the processor.

22. Apparatus comprising:
piezoelectric resonator means for resonating in response to a first input signal, the piezoelectric resonator means formed over an insulating substrate, a portion of the piezoelectric resonator means spaced apart from the substrate by a first gap; and
passive circuit component means for providing an electrical characteristic in response to a second input signal, the passive circuit component means formed over the insulating substrate, a portion of the passive circuit component means spaced apart from the substrate by a second gap;
the first gap and the second gap defined by removal of a sacrificial (SAC) layer.

23. The apparatus of claim 22, wherein the piezoelectric resonator means and the passive circuit component means includes a shared piezoelectric layer.

24. The apparatus of claim 22, wherein the piezoelectric resonator means and the passive circuit component means includes one or more shared conductive layers.
